(19) United States
(12) Patent Application Publication
(10) Pub. No.: US 2004/0009431 A1
(43) Pub. Date: Jan. 15, 2004

(54) Method of exposing semiconductor device

(75) Inventors: Atsushi Amo, Tokyo (JP); Atsushi Hachisuka, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/298,653

(22) Filed: Nov. 19, 2002

(30) Foreign Application Priority Data
Jul. 11, 2002 (JP) 2002-202388

(51) Int. Cl. G03F 7/20

(52) U.S. Cl. 430/311; 430/394; 430/319

(57) ABSTRACT

In a semiconductor exposure apparatus (10), four blinds (3a-3d) movable back and forth in the horizontal direction are provided on a path of light (L), to allow an irradiated region with light (L) on a mask (4) to be limited to an arbitrary rectangular region. On the other hand, a plurality of mask patterns different from each other are formed on the mask (4). When exposing one of the patterns, the blinds (3a-3d) are arranged such that the irradiated region with light (L) is positioned only over the one of the patterns and the periphery of the one of the patterns is shielded. This allows the plurality of mask patterns to be exposed with the single mask (4), achieving a reduction in costs for mask manufacturing and manufacturing time.

### BACKGROUND OF THE INVENTION

1. Field of the Invention

The present invention relates to a mask for semiconductor manufacturing for use in various types of patterning when manufacturing a semiconductor device.

2. Description of the Background Art

A mask for semiconductor manufacturing is an original when forming a pattern in a photolithography step which is one process among manufacturing steps of a semiconductor device. In such photolithography step, a pattern formed on a mask is transferred to a resist on a wafer as it is to form a resist pattern. Etching and implantation are performed in accordance with the resist pattern, thereby forming a semiconductor device on the wafer.

FIG. 11 shows a conventional mask 500 viewed from above. The conventional mask 500 is an illustration of a mask for a wiring step. Hereinafter, a positive resist, part of which irradiated with light disappears through development is assumed to be used in photolithography in this wiring step. The conventional mask 500 has an external frame 101, which is generally formed of a glass substrate.

Exposure is performed for a shot region 511 inside a shot frame 511f. Throughout the present specification, each exposure process is called a “shot”, a region in which a shot is conducted is called a “shot region”, and a frame surrounding a shot region is called a “shot frame”.

Hatched regions in the shot region 511 are light shielding regions 512 formed of, e.g., Cr film or MoSi film, on the surface of the mask 500. Exposing a resist-applied substrate using the mask 500 allows part of the resist at the light shielding regions 512 to remain after development while the other part of the resist at a region through which light is transmitted is removed in a region on the substrate that corresponds to the shot region 511. Accordingly, a resist pattern of a shape corresponding to the light shielding regions 512 is formed on the substrate.

A peripheral light shielding region 102 is further formed outside the shot frame 511f. This is to prevent regions other than the shot region 511 from being exposed to light in a single exposure process. These regions are sequentially exposed after the mask is moved.

In addition to the aforementioned elements, a mask is actually provided with a reticle alignment mark used for aligning the mask with an exposure apparatus and a mark for identifying the mask, and besides, a pellicle attached for protecting the mask against dusts, which, however, have no essential relations with the description of the present invention, explanation of which is thus omitted throughout the present specification.

Further, although a region through which light is transmitted, called a slit, is generally provided up to several μ meters from the outside of the shot frame 511f such that a thin resist does not remain even if a clearance occurs between adjacent shots, explanation thereof is omitted for simplification of description.

Hereinafter, substantial part used in exposing an essential circuit pattern is referred to as “mask”.

Conventionally, a mask as that shown in FIG. 11 has been required for each step of forming a pattern. On the other hand, device miniaturization, an increase in the number of wiring layers and the like have increased the number of photolithography steps, i.e., the number of masks necessary for manufacturing one device. Further, more precise masks have been required, which problematically increases costs and time necessary for mask manufacturing. For instance, a five-level interconnection Logic device requires approximately 30 to 40 masks at a 0.15-μm rule.

In large-scale mass production, mask-related costs constitute a small proportion of total costs. In small-scale mass production, prototype manufacturing or process development, however, it is becoming necessary to shorten mask manufacturing time and to reduce mask-related costs.

### SUMMARY OF THE INVENTION

An object of the present invention is to provide an exposure method capable of reducing the number of masks required for manufacturing one device.

The present invention is directed to a method of exposing a predetermined pattern on a substrate using a mask. The method includes the following steps (a) and (b). The step (a) is to shield the mask to limit an irradiated region with light on the mask. The mask has a surface on which a plurality of mask patterns different from each other corresponding to steps different from each other, respectively, are formed. The step (b) is to irradiate the light on the substrate through the irradiated region as limited.

Light for exposure can be irradiated only on a predetermined region on the mask, making it possible to selectively expose only part of patterns on the mask including the plurality of mask patterns.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 schematically shows a structure of a semiconductor exposure apparatus;

FIGS. 2A and 2B are explanatory views each showing a blind section;

FIG. 3 is a top view of a mask;

FIG. 4 is an explanatory view of the case of performing exposure in a first wiring step using the mask shown in FIG. 3;

FIG. 5 shows combinations of patterns in a photolithography process of a four-level interconnection CMOS device;

FIG. 6 shows a mask on which patterns are formed;

FIG. 7 is a sectional view showing a substrate after forming gate patterns;

FIG. 8 shows a mask as an illustration on which patterns for four wiring steps are formed;

FIG. 9 shows combinations of patterns in the photolithography process of the four-level interconnection CMOS device;

FIG. 10 shows an example of a revised mask; and

FIG. 11 is a top view of a conventional mask.

### DESCRIPTION OF THE PREFERRED EMBODIMENTS

<First Preferred Embodiment>

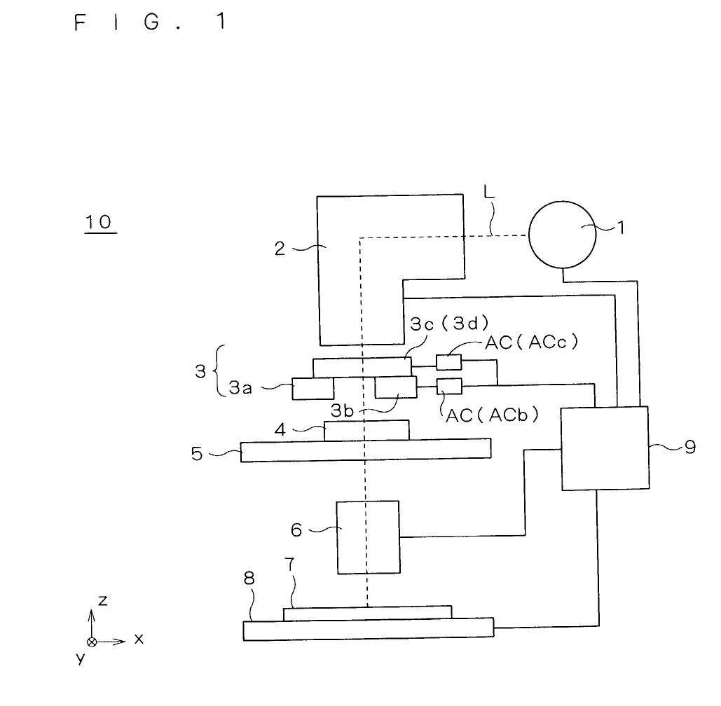

FIG. 1 schematically shows a structure of a semiconductor exposure apparatus 10 called a reduction projection aligner. As shown in FIG. 1, the semiconductor exposure apparatus is intended for irradiating light L to a mask 4 also called a reticle, so that a pattern formed on the mask 4 is projected onto a substrate 7 on a reduced scale for exposure. For this purpose, the semiconductor exposure apparatus 10 mainly includes a light source 1 which is a mercury lamp or laser for emitting light L for exposure having a certain wavelength, an illumination optical system 2 for modifying light L from the light source 1 into a desired state, a blind section 3 provided immediately above the arrangement position of the mask 4 for blocking part of light L passing through the illumination optical system 2 to limit an irradiated region on the mask 4, a reticle stage 5 for holding the mask 4, a reduction optical system 6 for projecting a pattern on a reduced scale, an exposure stage 8 with the substrate 7 mounted thereon for moving in the horizontal direction for accomplishing positioning of exposure, and a control unit 9 for controlling the operation of the respective components. FIG. 1 shows three-dimensional coordinates having an x-y surface along which the exposure stage 8 moves and a z-axis along which light L is incident, which is perpendicular to the x-y surface. Drawings which will be hereinafter referred to are in accordance with this coordinate system.

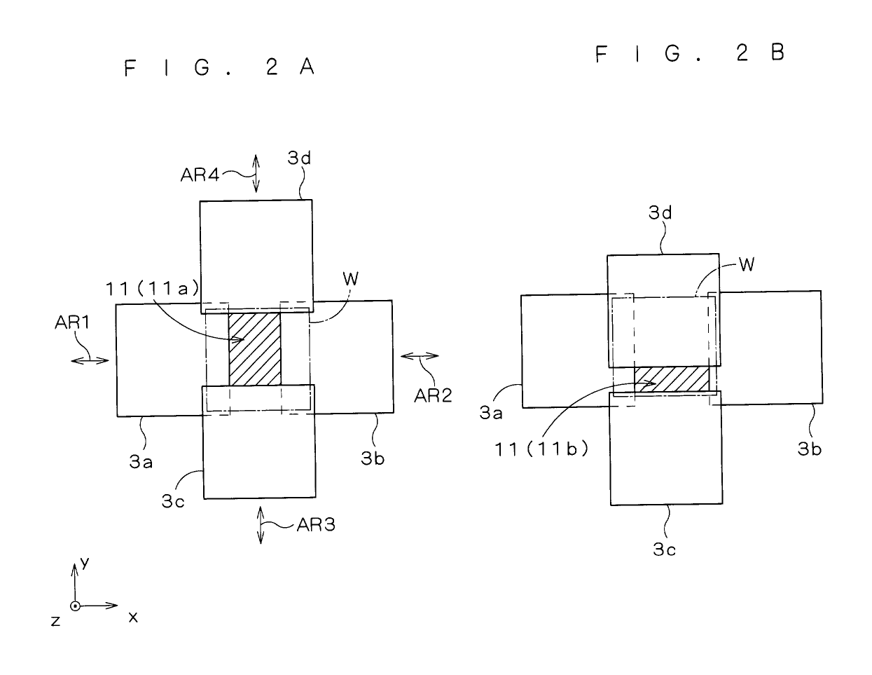

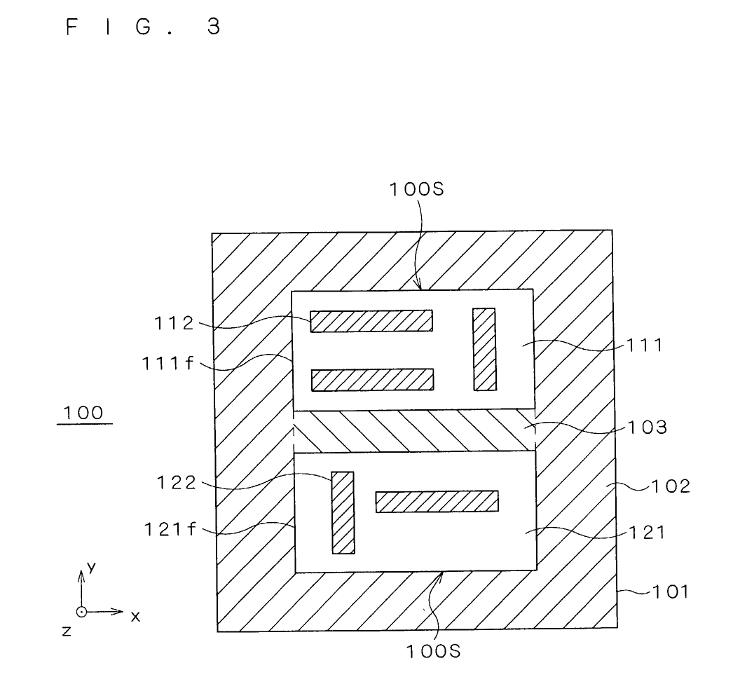

FIGS. 2A and 2B are explanatory views each showing the blind section 3. The blind section 3 is composed of four blinds (shielding plates) 3a, 3b, 3c and 3d and is provided immediately above the mask 4. The blinds 3a to 3d are provided with actuators AC (ACa, ACb, ACc and ACd), respectively, as driving means for moving the respective blinds 3a to 3d back and forth in the horizontal direction in response to predetermined signals from the control unit 9. The blinds 3a and 3b are provided to face each other, and move along the x-axis as indicated by arrows AR1 and AR2 under the action of the actuators ACa and ACb, respectively, in response to a predetermined control signal from the control unit 9. The blinds 3c and 3d are provided to face each other over the blinds 3a and 3b, and move along the y-axis as indicated by arrows AR3 and AR4 under the action of the actuators ACc and ACd, respectively, in response to a predetermined control signal from the control unit 9. Therefore, the moving direction of the first pair of the blinds 3a and 3b and that of the second pair of the blinds 3c and 3d are perpendicular to each other. With the semiconductor exposure apparatus 10 according to the present embodiment, appropriate arrangement of the blind section 3 allows an irradiated region 11 with light L on the mask 4 to be limited to a rectangular region which varies in size and position. FIGS. 2A and 2B illustrate the cases where irradiated regions 11a and 11b different from each other are formed. Since the blind section 3 is provided immediately above the mask 4, light L is irradiated on the irradiated region 11 without fail.

FIG. 3 shows a mask 100 viewed from above as an example of the mask 4 shown in FIG. 1. The mask 100 includes the external frame 101 and the peripheral light shielding region 102 formed of e.g., Cr film or MoSi film on its surface, similarly to the conventional mask 500 shown in FIG. 11.

Further, the mask 100 is characterized in that two shot regions 111 and 121 having different patterns formed thereon, respectively, are formed on a flat mask surface 100S surrounded by the external frame 101 and peripheral light shielding region 102. That is, the mask 100 is used in two different photolithography steps. Here, the two steps shall be first and second wiring steps, respectively. The first wiring step is to perform exposure in accordance with a wiring pattern 112 including light shielding portions formed in the shot region 111 surrounded by a shot frame 111f, and the second wiring step is to perform exposure in accordance with a wiring pattern 122 including light shielding portions formed in the shot region 121 surrounded by a shot frame 121f. An inter-pattern light shielding region 103 is formed between the two shot regions 111 and 121. The region 103, intended for shielding the outside of the shot regions 111 and 121, similarly to the peripheral light shielding region 102, is characterized by having a width of approximately 200 to 600 μm between the shot frame 111f for the first wiring step and the shot frame 121f for the second wiring step. The width of the region 103 is determined based on the positional accuracy of the blind section 3.

In the semiconductor exposure apparatus 10 according to the present embodiment, using the mask 100 and adjusting the arrangement of the respective blinds 3a to 3d of the blind section 3 as shown in FIGS. 2A and 2B achieves the use of the single mask 100 for two lithography steps.

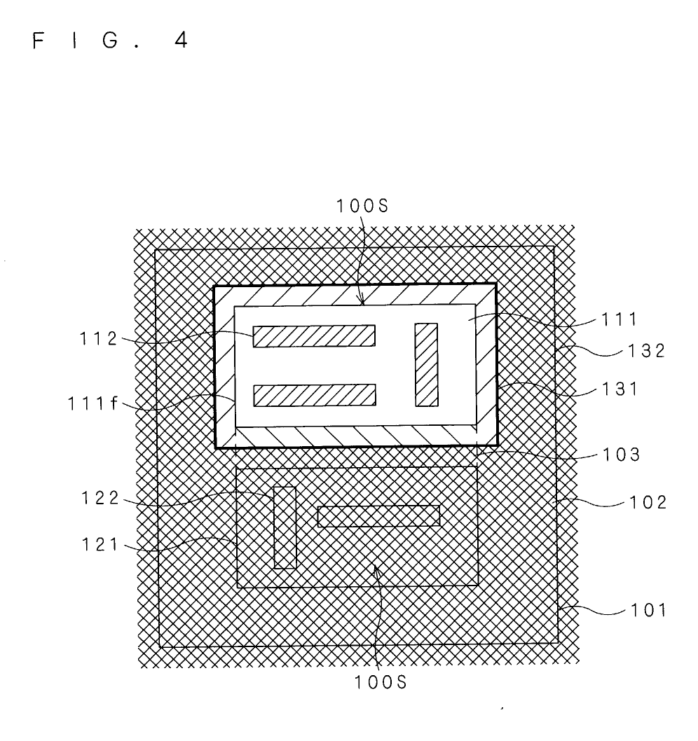

FIG. 4 is an explanatory view of the case of performing exposure for the first wiring step using the mask 100. First, in exposure for the first wiring step, the blind section 3 is arranged such that an irradiated region 131 is positioned only over the shot region 111 and is surrounded by a light shielding region 132. Irradiating light L in this state allows only the pattern for the first wiring step to be exposed to the substrate 7 through the irradiated region 131 limited on the mask 100. Then, a development process, exposure with another mask and the like are carried out, followed by the stage of performing exposure for the second wiring step, where the mask 100 and substrate 7 are set again, and the blind section 3 is arranged such that the irradiated region 11 is positioned over the shot region 121, thereby exposing only the shot region 121.

From the foregoing, two wiring steps which conventionally have required two different masks, respectively, can be performed with a single mask, thus reducing costs and time required for mask manufacturing by half.

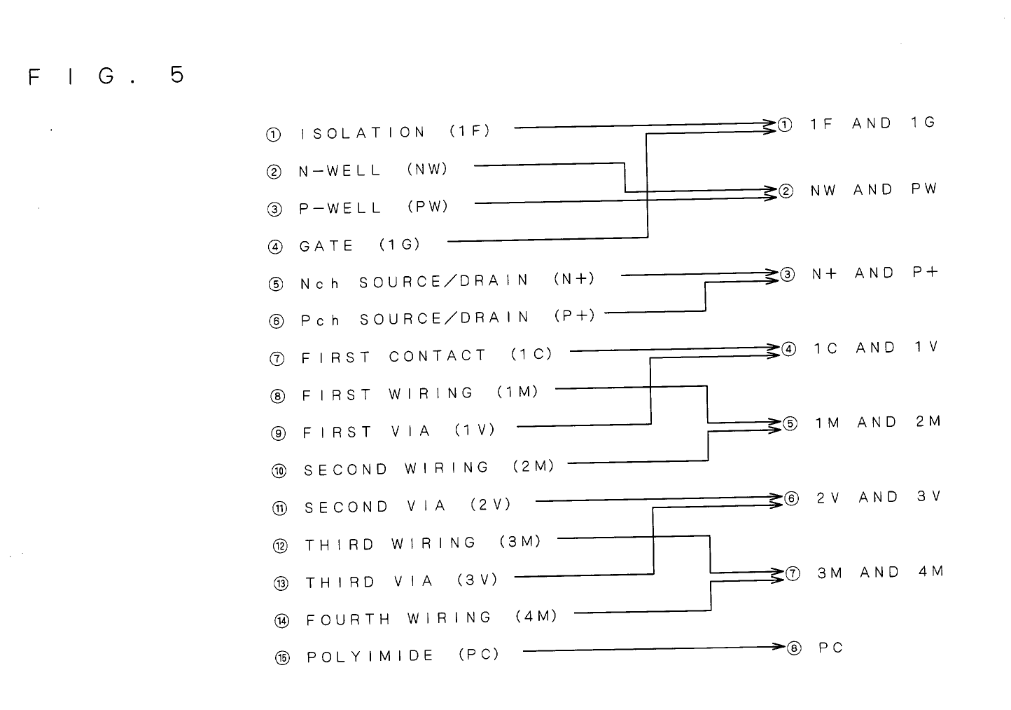

As an example through the use of the foregoing, FIG. 5 shows a photolithography process of a four-level interconnection CMOS device manufactured through fifteen steps of photolithography. As indicated in the left column of FIG. 5, the fifteen photolithography steps are the process sequentially performing exposure with mask patterns of (1) isolation pattern 1F, (2) N-well pattern NW, (3) P-well pattern PW, (4) gate pattern 1G, (5) Nch source/drain pattern N+, (6) Pch source/drain pattern P+, (7) first contact pattern 1C, (8) first wiring pattern 1M, (9) first via pattern 1V, (10) second wiring pattern 2M, (11) second via pattern 2V, (12) third wiring pattern 3M, (13) third via pattern 3V, (14) fourth wiring pattern 4M and (15) polyimide pattern PC. In the case where one photolithography step requires one mask as in the conventional case, the fifteen photolithography steps require fifteen masks. However, as in the present embodiment, forming mask patterns for two steps on a single mask, forming on the same mask each pair of patterns: the isolation pattern 1F and gate pattern 1G; N-well pattern NW and P-well pattern PW; Nch source/drain pattern N+ and Pch source/drain pattern P+; first contact pattern 1C and first via pattern 1V; second via pattern 2V and third via pattern 3V; first wiring pattern 1M and second wiring pattern 2M; and third wiring pattern 3M and fourth wiring pattern 4M (the polyimide pattern PC is formed alone on a single mask) as indicated in the right column of FIG. 5, for example, will allow all the steps to be performed with eight masks, so that the number of masks can be reduced substantially by half.

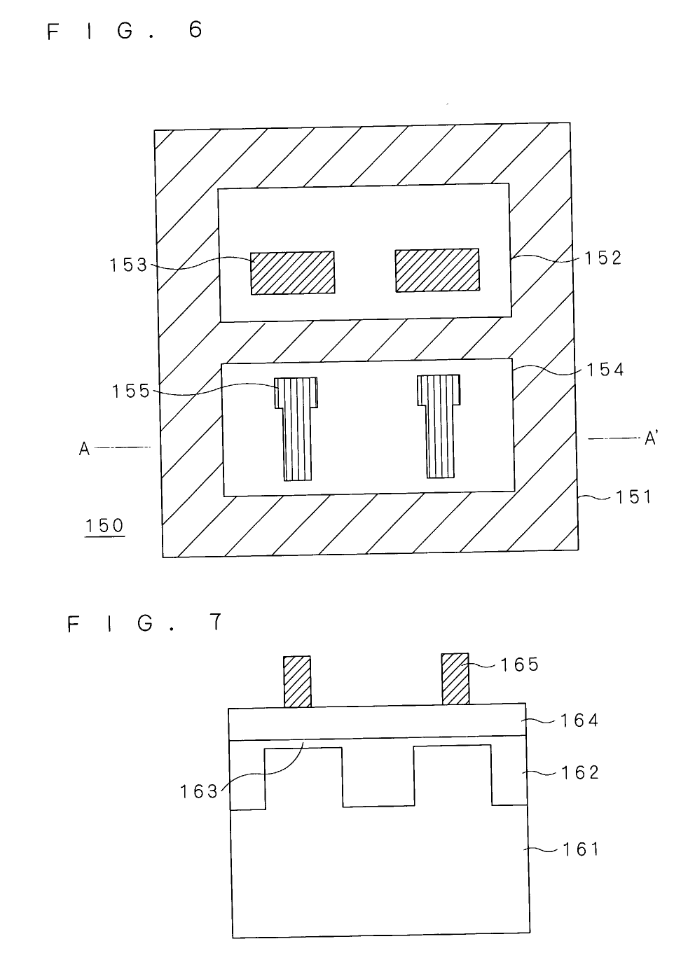

As an example of the eight masks, FIG. 6 shows a mask 150 having the isolation pattern 1F and gate pattern 1G formed thereon. The mask 150 includes an external frame 151, a shot region 152 of the isolation pattern 1F, a mask pattern 153 thereof, a shot region 154 of the gate pattern 1G and a mask pattern 155 thereof.

FIG. 7 is a sectional view of the substrate after performing photolithography of the mask pattern 155 to form the gate pattern 1G with a resist. FIG. 7 corresponds to a cross-section taken along the line A-A′ of FIG. 6, showing the state in which an isolation oxide film 162 is formed on a substrate 161 in accordance with the mask pattern 153 as the isolation pattern 1F, and a gate oxide film 163 and polysilicon 164 to be a gate electrode are further formed in this order, thereby forming the gate pattern 1G with a resist 35 in accordance with the mask pattern 155 as the gate pattern 1G shown in FIG. 6.

It is preferable that the following two points be taken into consideration when forming patterns for a plurality of steps on a single mask.

The fist consideration is the presence of unpreferable combinations of patterns. Generally, in the example shown in FIG. 5, a halftone mask is used for a hole step using the first contact pattern 1C and first via pattern 1V, etc., and a normal mask is used for a wiring step using the first wiring pattern 1M and second wiring pattern 2M, etc. This is because hole patterns are more difficult to resolve than line patterns, so that a halftone mask having resolution higher than that of a normal mask is used in many cases for the first contact pattern 1C and first via pattern 1V which are hole patterns, and a normal mask is used for the first wiring pattern 1M and second wiring pattern 2M, and because light shielding portions of the respective masks are made of different materials (a normal mask is made of Cr, MoSi, etc. while a halftone mask is made of MiSiOn, CrON, etc.) in order to achieve different degrees of light transmittivity.

Therefore, in the above-described example, it is not preferable to form the first contact pattern 1C and first wiring pattern 1M on the same mask, but is preferable to select combinations such as those of the first contact pattern 1C and first via pattern 1V, and the first wiring pattern 1M and second wiring pattern M2.

It is further preferable to form, on the same mask, patterns which have the same address units (grids for moving beams in electron beam lithography of mask patterns) required at mask manufacturing and the same dimensional accuracy in forming mask patterns thereon. On a mask formed by patterns of fine size which is required to have high dimensional accuracy, mask patterns are formed using a smaller address unit, thus increasing time and further, costs for electron beam lithography. It is useless to perform lithography using the same address unit on a mask for a step not requiring such smaller address unit. In the example shown in FIG. 5, the isolation pattern 1F and gate pattern 1G are formed by patterns of finer size than the N-well pattern NW, P-well pattern PW, Nch source/drain pattern N+ and Pch source/drain pattern P+ for implantation steps, and are required to have high dimensional accuracy. For instance, it is not preferable to form a mask with a combination of the isolation pattern 1F and N-well pattern NW.

The second consideration is a limitation of reducing shot regions in size. In the conventional exposure apparatus, the maximum exposure region on the wafer, i.e., the maximum shot size is approximately 22 mm-by-22 mm. However, in the case where the exposure region is divided by half and an inter-pattern light shielding region is further provided, the maximum shot size becomes approximately 22 mm-by-10.75 mm assuming that the inter-pattern light shielding region is approximately 500 μm in width. In this regard, the exposure method of the present invention is sufficiently applicable if a chip to be exposed falls within this range of size.

Further, a multi-chip reticle with the maximum utilization of an exposure region cannot be formed, which makes it difficult to achieve improved throughput of the semiconductor exposure apparatus, however, assumed major applications of the present invention are as prototype manufacturing and low-volume production, thus causing no problem in implementation.

As has been described, according to the present embodiment, the number of masks used in photolithography steps can be reduced, thus making it possible to reduce costs for mask manufacturing and to shorten manufacturing time.

<Second Preferred Embodiment>

Although patterns for two steps are formed on a single mask in the first preferred embodiment, patterns corresponding to more steps can be formed on a single mask.

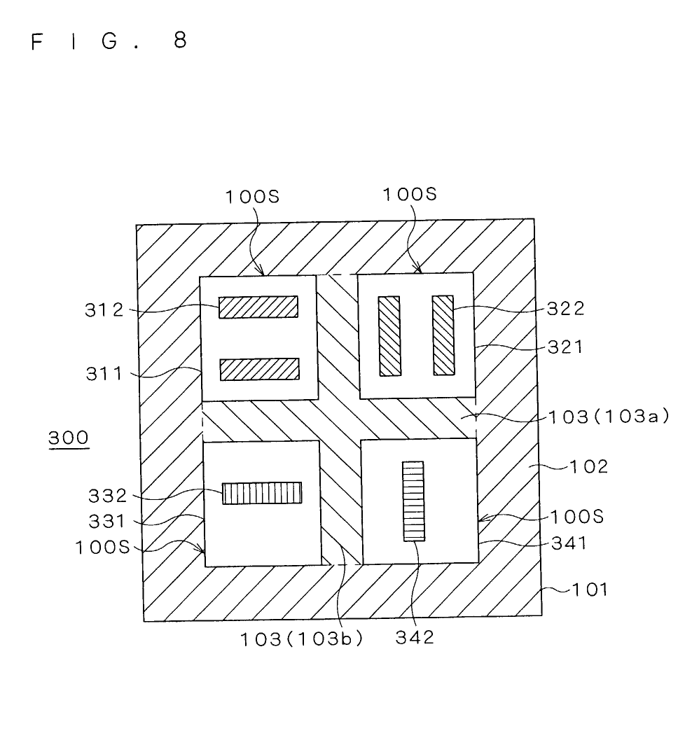

FIG. 8 shows a mask 300 as an illustration on which patterns for four wiring steps are formed. The mask 300 shall have four shot regions 311, 321, 331 and 341 formed on the exposable flat mask surface 100S surrounded by the external frame 101 and peripheral light shielding region 102, on which patterns 312, 322, 332 and 342 respectively corresponding in this order to the first, second, third and fourth wiring steps shall be formed, respectively. The inter-pattern light shielding region 103 (103a, 103b) shields regions between the respective shot regions 311, 321, 331 and 341.

In the present embodiment, the blind section 3 is also arranged so as to provide an irradiated region corresponding to each shot region at each time of exposure for each wiring step, thereby performing an exposure process, as in the first preferred embodiment.

From the foregoing, patterns for four wiring steps which conventionally have required four different masks, respectively, can be formed on a single mask, thus reducing costs for mask manufacturing and significantly shortening manufacturing time.

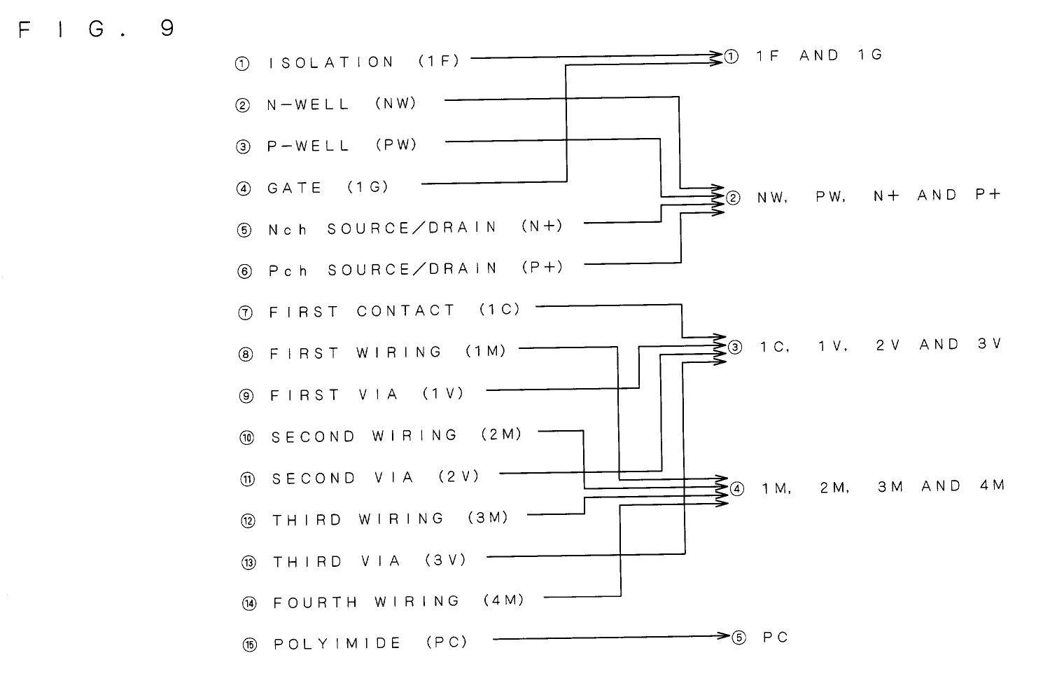

For instance, as shown in FIG. 9, the photolithography process for the four-level interconnection CMOS device described in the first preferred embodiment can be performed with five masks in total by forming patterns for a maximum of four steps on a single mask, allowing a reduction of the number of masks by one third.

<Third Preferred Embodiment>

In prototype manufacturing and product development stage, design changes require revisions/changes of mask patterns in many cases. In such cases, suppression of increases in costs and manufacturing time is required. The present invention is also applicable for such cases.

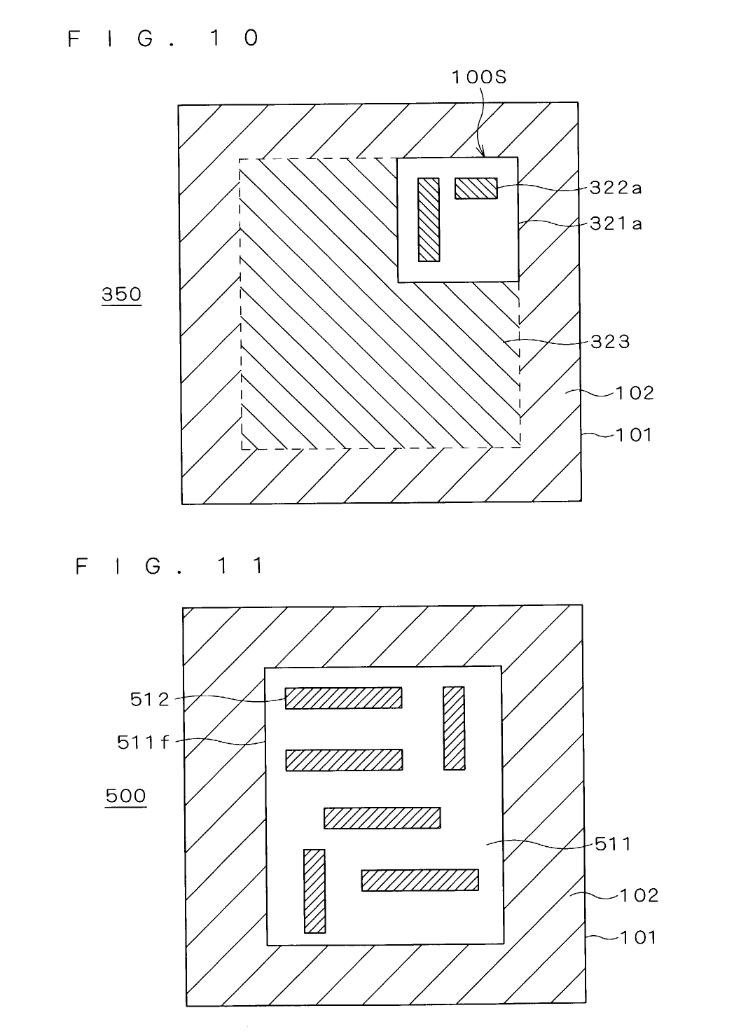

FIG. 10 shows an example of a revised mask 350 in the case where a revision becomes necessary only for the pattern 322 corresponding to the second wiring step in the photolithography step using the mask 300 according to the second preferred embodiment. On the mask surface 100S, the revised mask 350 includes a shot region 321a having the same size as and located at the same position as the shot region 321 corresponding to the second wiring step of the mask 300 according to the second preferred embodiment. A revised pattern 322a is formed in the shot region 321a, while a light shielding region 323 is formed in all regions corresponding to the other patterns.

By preparing such revised mask 350, the mask 350 is used only in exposure for the second wiring step and the mask 300 before revision is used as it is for the first, third and fourth wiring steps.

As has been described, a pattern necessary to be revised is determined as a to-be-revised pattern, and only part that corresponds to the to-be-revised region is made over, allowing lithography time at mask manufacturing to be shortened as well as reducing time and work required for test and modification of masks as compared to the case of making over all the masks. As a result, costs for manufacturing revised masks can be minimized and manufacturing time can be shortened, allowing a quick response to design changes.

<Variant>

Although patterns for two or four steps are formed on a single mask in the aforementioned respective embodiments, the present invention is not limited to those examples, but patterns for three or five steps or more may be formed on a single mask. However, an increase in the number of patterns for steps formed on the same mask reduces shot regions in size, so that an upper limit of the number of steps is determined depending on the size of shot regions of a device actually desired to be manufactured.

While the invention has been shown and described in detail, the foregoing description is in all aspects illustrative and not restrictive. It is therefore understood that numerous modifications and variations can be devised without departing from the scope of the invention.

What is claimed is:

1. A method of exposing a predetermined pattern on a substrate using a mask, comprising the steps of:
(a) shielding said mask to limit an irradiated region with light on said mask, said mask having a surface on which a plurality of mask patterns different from each other corresponding to steps different from each other, respectively, are formed; and
(b) irradiating said light on said substrate through said irradiated region as limited.

2. The method according to claim 1, wherein
said step (a) is performed by a shielding element provided immediately above an arrangement position of said mask.

3. The method according to claim 2, wherein
said shielding element includes two pairs of shielding plates, each pair being formed by two shielding plates provided to face each other, and
a moving direction of two shielding plates forming one of said two pairs is perpendicular to that of two shielding plates forming the other of said two pairs.

4. The method according to claim 3 further comprising the step of
(c) sequentially exposing each of said plurality of mask patterns provided on said mask, wherein
in said step (a), said irradiated region can be arranged in accordance with one of said plurality of mask patterns to be exposed in said step (c).
